(19) United States
(12) Patent Application Publication
(10) Pub. No.: US 2024/0281636 A1
(43) Pub. Date: Aug. 22, 2024

(54) DATA OPTIMIZATION FOR HIGH BANDWIDTH (HBW) NVM AI INFERENCE SYSTEM

(71) Applicant: MACRONIX INTERNATIONAL CO., LTD., HSINCHU (TW)

(72) Inventors: I-Ting KUO, TAOYUAN (TW); Hsiang-Lan LUNG, ARDSLEY, NY (US)

(73) Assignee: MACRONIX INTERNATIONAL CO., LTD., HSINCHU (TW)

(21) Appl. No.: 18/112,827

(22) Filed: Feb. 22, 2023

(51) Int. Cl. G06N 3/04; G06N 3/063

(52) U.S. Cl. CPC G06N 3/04; G06N 3/063

(57) ABSTRACT

A method for storing weight data used to compute node values during inferencing operations conducted by a neural network comprises receiving a neural network definition. The neural network definition defines a neural network having a plurality of layers, each having a plurality of nodes. A set of weights used to compute a neural network inferencing result for each neural network node of the plurality of network nodes in the layer is determined. The set of weights determined for the layer in a page of memory can be stored in a high bandwidth non-volatile memory (NVM), such that any weights used to compute the neural network inference result for each neural network node of the plurality of nodes in the layer are stored together in the page of memory for retrieval together. Weights can be stored in different arrays across multiple memory channels.

### RELATED APPLICATION

This application is being filed concurrently with commonly owned, commonly invented US Patent Application No. ______, titled “HIGH BANDWIDTH NON-VOLATILE MEMORY FOR AI INFERENCE SYSTEM”, (Attorney Docket Number MXIC 2342-1), which is incorporated in its entirety herein for all purpose.

### BACKGROUND

### Field

The present technology relates to integrated circuit memory devices, such as non-volatile memory devices, that support storage and retrieval of information used in artificial intelligence (AI) inferencing applications, and particularly relates to approaches for the storage and retrieval of AI inferencing (weight) data that fully leverage the greater bandwidth capabilities of AI memory architectures.

### Description of Related Art

Modern information technology applications, such as artificial intelligence (AI) inferencing can consume copious amounts of data such as weighting information in conduct of inferencing operations.

Many different types of memory architectures have been created, each providing storage of digital data and addressing different needs and requirements of a variety of applications. However, conventional approaches to memory devices often suffer from insufficient bandwidth, leading to poor performance, or require refresh logic and are therefore higher in cost.

Numerous reads/writes especially in AI applications, where there can be hundreds of millions of reads/writes, consume a great deal of power and require significant processing time. Therefore, a need arises for an AI inference platform that has higher bandwidth and lower power consumption by reducing the read/write time and the number of read/write operations.

It is desirable to provide mechanisms for the storage and retrieval of AI inferencing (weight) data that fully leverage the greater bandwidth capabilities of AI memory architectures.

### SUMMARY

The present technology provides for storing weight data used to compute node values during inferencing operations on a neural network enabling a reduced number of read operations and associated read times and reduced power consumption. Such operations may be conducted by an artificial intelligence (AI) accelerator processing core or cores (e.g., accelerator core) of an AI inference platform coupled with a NAND flash or other high bandwidth memory architecture. The method can be implemented in logic disposed within an AI inference memory device or in a nonvolatile storage coupled to a neural processing unit (NPU) of an AI inference platform employing a high bandwidth (HBW) NAND flash technology as well as other HBW types.

In a representative implementation and by way of example, a method for storing weight data used to compute node values during inferencing operations conducted by a neural network comprises receiving by an AI accelerator of an artificial intelligence inferencing platform, a neural network definition. The neural network definition defines a neural network having a plurality of layers. A layer comprises a plurality of neural network nodes. A neural network node uses one or more weights to compute a result for the node by applying a function to (i) the one or more weights and (ii) an input to the node during an inferencing operation. Determining for a layer of the plurality of layers defined in the neural network definition, a set of weights to use to compute a neural network inferencing result for each neural network node of the plurality of network nodes in the layer is also part of the method. The set of weights determined for the layer in a page of memory can be stored in a high bandwidth NVM such that any weights of the set of weights used to compute the neural network inference result for each neural network node of the plurality of nodes in the layer are stored together in the page of memory for retrieval together.

In another example implementation, the method further includes processing a next layer in the neural network definition, such that a second set of weights used to compute a neural network inference result for the next layer are also stored together in the page of memory for retrieval together.

In a further implementation, weights in the set of weights can be assigned to groups of weights and each group of weights is assigned to a channel in the neural network definition. Weights of a particular channel can be stored together such that weights of two or more groups of weights used to compute the neural network inference result for each neural network node of the plurality of nodes in the layer are retrieved sequentially without necessitating a read of an additional page of memory.

In a yet further implementation, retrieving the weights of the two or more groups of weights can include retrieving all groups for the layer without necessitating a read of an additional page of memory.

In a still further implementation, each group of weights corresponds to a particular channel of the neural network. For example, a neural network configured to process images can include channels for red (R), green (G), and blue (B).

In a yet still further implementation, each channel of the neural network corresponds to a filter populated by the weights of a respective group of weights. For example, filters of each corresponding channel can comprise weights arranged in a pattern selected from a 3×3 pattern, a 4×4 pattern, a 5×5 pattern, and a 6×6 pattern.

In a yet still further implementation, weights are stored to and read from one or more dies implementing non-volatile storage arrays using a plurality of memory channels, which provide pathways for data transfer to and from the NVM dies. For example, all of the weights belonging to a group can be allocated to a particular memory channel. In another example, weights belonging to a group are apportioned among multiple memory channels.

In a yet still further implementation, each weight in the set of weights can be retrieved from a previous storage location in memory prior to storing the set of weights determined for a layer in a page of memory; thereby re-arranging weight data in the memory.

In another representative implementation providing further example, an artificial intelligence (AI) inference memory device comprises a plurality of non-volatile memory (NVM) dies, each of the NVM dies including at least one memory array and a plurality of connections to corresponding channel logic to provide storage into and retrieval from the memory array. The NVM dies can be operatively coupled with a neural processing unit (NPU) implementing an accelerator core connected via the corresponding channel logic for conducting data to and from the memory arrays and configured to implement the described methods for storing weight data used to compute node values during artificial intelligence (AI) inferencing operations conducted by a neural network.

In a further representative implementation providing a further example, an AI inference system comprises a plurality of non-volatile memory (NVM) dies, each of the NVM dies including at least one memory array and a plurality of connections to corresponding channel logic to provide storage into and retrieval from the memory array. The AI inferencing system can further include a neural processing unit (NPU) implementing an accelerator core connected via the corresponding channel logic for conducting data to and from the memory arrays and configured to implement the described methods for storing weight data used to compute node values during artificial intelligence (AI) inferencing operations conducted by a neural network. These components can be disposed on a common interposer or substrate or distributed among multiple packages.

In a still further representative implementation providing a further example, a non-transitory memory is provided that stores instructions for storing weight data used to compute node values during artificial intelligence (AI) inferencing operations conducted by a neural network, which when, executed by one or more processors implement the described actions for receiving a neural network definition, determining for a layer of a plurality of layers defined in the neural network definition, a set of weights to use to compute a neural network inferencing result for each neural network node of the plurality of network nodes in the layer, and storing weight data used to compute node values during artificial intelligence (AI) inferencing operations conducted by a neural network.

Weight data storage paradigms in accordance with embodiments described herein can reduce flash access times and increase data process efficiency. Other aspects and advantages of the present technology can be seen on review of the drawings, the detailed description and the claims, which follow.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a simplified diagram illustrating storage and retrieval of weight data in a memory system including a flash memory device implemented on an integrated circuit as described herein.

FIG. 2 illustrates weight data used by a neural network to process images being stored according to various storage paradigms by a high bandwidth non-volatile memory (NVM) in accordance with the technologies as described herein.

FIG. 3 is a schematic illustration of a technique of allocating weight data among multiple NVM channels by a high bandwidth NVM in accordance with the technologies as described herein.

FIG. 4 is a schematic diagram illustrating multiple scenarios for allocating weight data among multiple NVM channels by a high bandwidth NVM in accordance with the technologies as described herein.

FIG. 5 is a flowchart illustrating an example of a weight data storage operation that can be executed by an inference system as described herein.

FIG. 6 is a simplified functional block diagram of a representative neural network node (neuron) including weight data stored into and read out from a high bandwidth NVM by the AI inference system logic as described herein.

FIG. 7 illustrates representative activation functions suitable for implementing artificial intelligence inferencing as described herein.

FIG. 8 is a simplified functional block diagram of an inference system as described herein.

FIG. 9 is an illustration of a multichip module including a high bandwidth memory for artificial intelligence (AI) inferencing as described herein.

FIG. 10 is an illustration of another embodiment of a multichip module including a high bandwidth memory for AI inferencing as described herein.

FIG. 11 is an illustration of yet another embodiment of a multichip module including a high bandwidth memory for AI inferencing as described herein.

### DETAILED DESCRIPTION

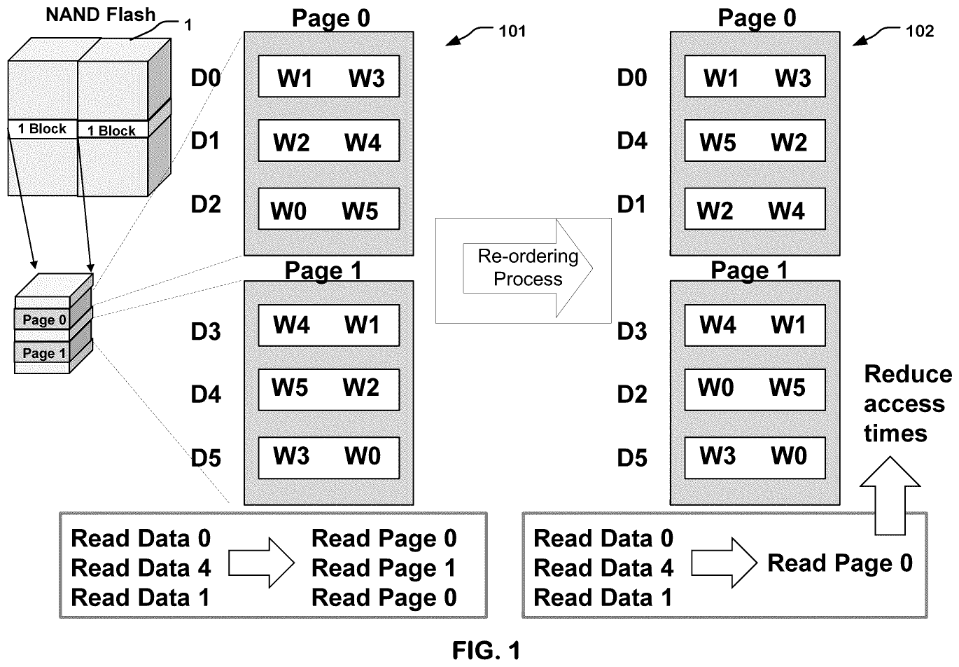

A detailed description of embodiments of the present technology is provided with reference to the FIGS. 1-11. Implementations as described herein embody a data optimization processes in methods, and hardware logic for use in storing weight data used in artificial intelligence (AI) inferencing operations to reduce data fetching required during reading of weight data to populate the neural network nodes and to thereby increase data throughput and AI inferencing process efficiencies.

In a typical AI inferencing platform configuration, an AI accelerator will fetch weight data to be used during AI inferencing from a high bandwidth (HBW) non-volatile memory (NVM) or HBW NAND. During such reading operations, NAND flash for example permits access granularity at the page level. Data fetching can become impaired when data is stored in different pages, requiring multiple page-fetching operations to obtain weight data for nodes of a neural network layer being populated. This can impact the processing throughput and/or speed of the overall process. In a critical case, the AI accelerator may even stall and wait for incoming data to arrive. Accordingly, implementations as described herein embody a data optimization processes in methods, and hardware logic to reduce data fetching required and increase data throughput and AI inferencing process efficiencies.

In process constrained environments, speed in which the AI application arrives at a result becomes an important factor. Thus conventional randomly stored weight data in the HBW NAND flash could increase data fetching operations required and lead to low data transmission efficiency due to the page-level granularity inherent to NAND flash page read operations. Weight data storage paradigms in accordance with embodiments described herein can reduce flash access times and increase data process efficiency.

FIG. 1 is a simplified diagram illustrating storage and retrieval of weight data used to compute node values during inferencing operations conducted by a neural network in a memory system including a flash memory device 1 implemented on an integrated circuit as described herein. The memory device can be implemented on a single integrated circuit chip, on a multichip module, or on a plurality of chips configured to suit a particular need.

As shown in FIG. 1, memory device 1 is a NAND flash in which read operations are performed at a one-page granularity, meaning that every time a fetch operation for data is performed, one whole page must be read from the flash. Data fetching can become slow when data is stored in different pages. This may impact the process speed of the entire AI inferencing platform. Further, the AI accelerator may stall and wait for data to arrive. This can result in low bandwidth utilization if locality of the data is not well preserved.

Continuing with FIG. 1, D0 to D5 indicate data storage locations; W0 to W5 indicate weight data. The weight data was stored in the NVM. In a first scenario 101, weight data (i.e., neural network weights) are stored randomly in data locations from location D0 to location D5 in page 0 and page 1. Accordingly, if neural network processing calls for weights W1, W5 and W2 to perform a calculation, i.e., obtain a node value or set of node values, then the NAND flash memory device 1 will read page 0 first, in order to obtain weight W1, then read page 1, in order to obtain weight W5, and then go back to re-read page 0, in order to obtain weight W2. However, if the data is stored in data locations in accordance with an expected retrieval indicated by the neural network to be processed, or re-ordered to be in such storage locations, as illustrated by second scenario 102, expected data acquisition times can be reduced. In second scenario 102, weights W1, W5 and W2 are all stored in locations in page 0. Thus, obtaining weights W1, W5 and W2 calls for the NAND flash memory device 1 to perform a single read of page 0, which reduces access time, increases efficiency, increases performance, etc.. In various implementations, the structure of the neural network, which indicates which weights are to be used and in what order, can be received as an input by the AI inferencing system, read from storage, or otherwise made accessible. Because the whole neural network structure can be obtained from a local storage on chip, received from a host or another chip in the AI inferencing system, the AI inferencing system can determine what weight data needs to be input during AI inference, and thus in what order the weight data can be stored in order to reduce access times during later inferencing.

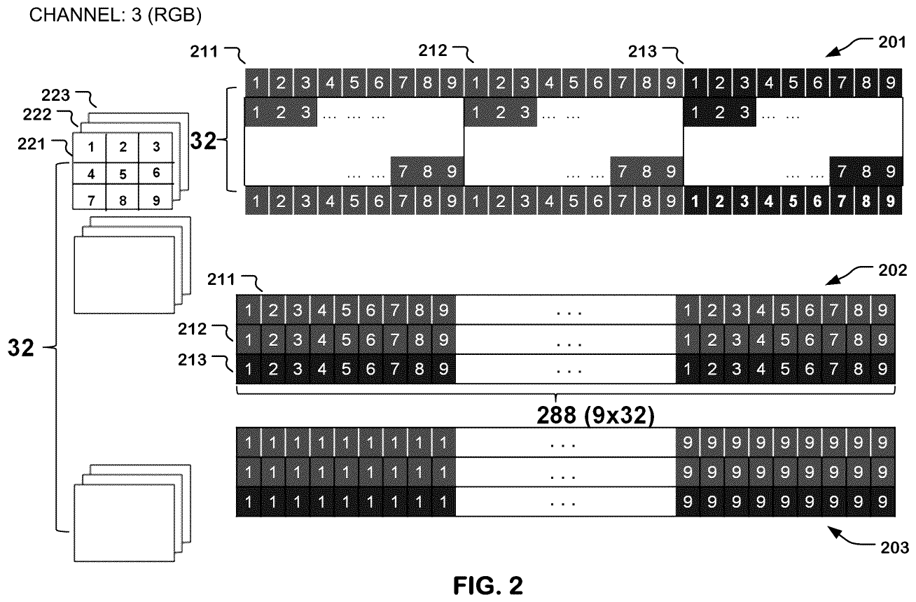

FIG. 2 illustrates weight data used by a neural network to process images being stored according to various storage paradigms by a high bandwidth NVM in accordance with the technologies as described herein. In the example implementation illustrated by FIG. 2, weight data is stored in the same page or multiple pages in the NVM and read in groups or sets of nine (9) weights for each of three (3) color neural network channels: red (1 to 9), green (1 to 9) and blue (1 to 9). A group (or set) of weights can comprise a filter or a feature map such that the filter can include weights that correspond to network nodes in a layer of the neural network defined in a neural network definition. In an implementation and by way of example, an input can be an input image of 224×224×3 pixels; where 3 is the number of channels, i.e., a red, a green, and a blue channel. However, an intermediate form of the data will become 224×224×64 after a first convolution processing is applied to the input image, because there are 64 3×3 filters (each comprising 9 weights) and each filter has 3 neural network channels, i.e., a red, a green, and a blue channel for convolutional neural network (CNN) processing.

In the example storage paradigms 201, 202, 203 illustrated by FIG. 2, there are 32 sets of 9 weights, each having a specific storage location, where a set of 9 weights 211, 212, 213 forms a respective 3×3 filter, e.g., 221, 222, 223. A set of 9 red weights 211 can be used to populate a red filter 221, a set of green weights 212 can be used to populate a green filter 222, and a set of blue weights 213 can populate a blue filter 223. Accordingly, there are 288 red weights (e.g., 32×9), 288 green weights and 288 blue weights. In sum, there is a total of 864 weights (288×3).

As depicted in FIG. 2, weights are stored from left to right in the diagram, which is from red to green to blue in paradigm 201. Accordingly, in paradigm 201, 3 fetch instances are needed to retrieve the first filter of 3 different, i.e., red, green, and blue channels, because, for example, this data might not be stored in the same page in memory, depending on the page size. Accordingly, for example, to populate each of the filters at least 96 read operations (32×3) will be required. If the weights are all stored in the same page, this processing can still require 3 read operations to obtain values for a filter for 3 different (e.g., R, G, and B) channels. That's why the order of the data can be re-arranged so that an AI inferencing engine can process all of the red data at once, if one page is large enough to hold all red data. If the page size is not large enough to hold the weights for all filters of the same color, the remainder of the same color weights will be stored continuing onto the next page in memory.

When the weight data is stored according to a first storage paradigm 201, resulting read processing that is of lower efficiency may result. If data location can be arranged (or re-arranged) and stored in a different ordering, such as paradigms 202, 203, then weight data can be read in once for red, green and blue filters. This will reduce data fetching times, resulting in decreased processing time during inferencing when the data needs to be read.

In paradigm 202, 9 weights for a red filter 211, 9 weights for a green filter 212 and 9 weights for a blue filter 213 have been stored together. In this configuration, a read operation can obtain weights to populate filters 221, 222, and 223 in a single read operation.

In paradigm 203, weights are arranged with all Is grouped together, then all 2s grouped together, and so forth. This is another data re-arrangement to improve access when performing convolution processing. The input image will multiply 3×3 filter to do convolution processing. The processing in this paradigm is the same as in paradigm 202. Weights stored in the same location are comprised of red, green and blue stored together. In paradigm 202, all of the weights from filters 221, 222 and 223 are stored together. In paradigm 203, Weights from all filter 221, e.g., weights 1s, 2s and so on, are stored together. This different arrangement produces the same desired effect.

Of course, while 3×3 filters are used in this example illustrated by FIG. 2, filters could be constructed having practically any size, such as for example and without limitation embodiments that implement filters of 5×5, 8×8, in which cases, there would be 25, or 64, etc. total weight values per filter.

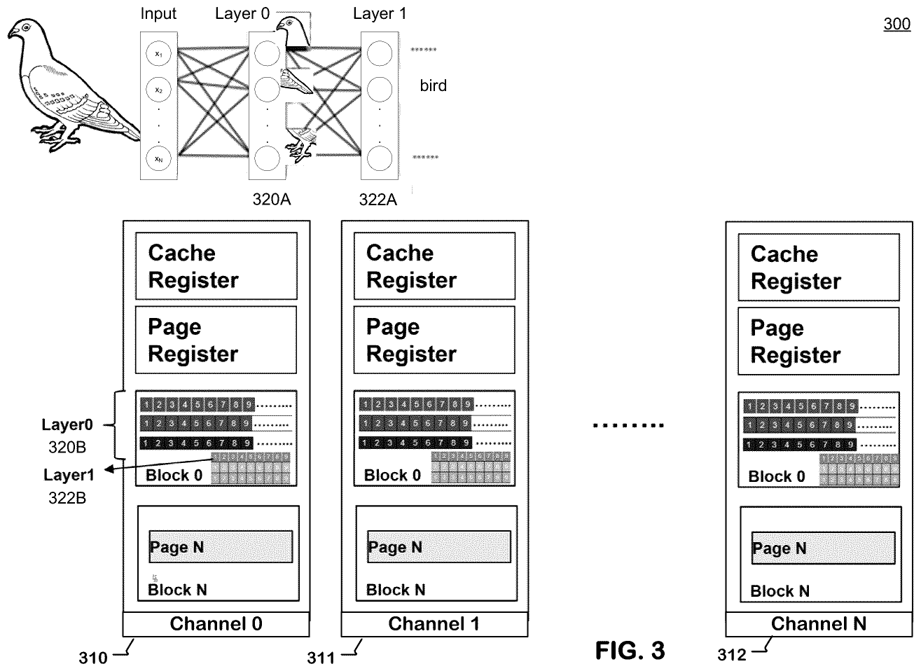

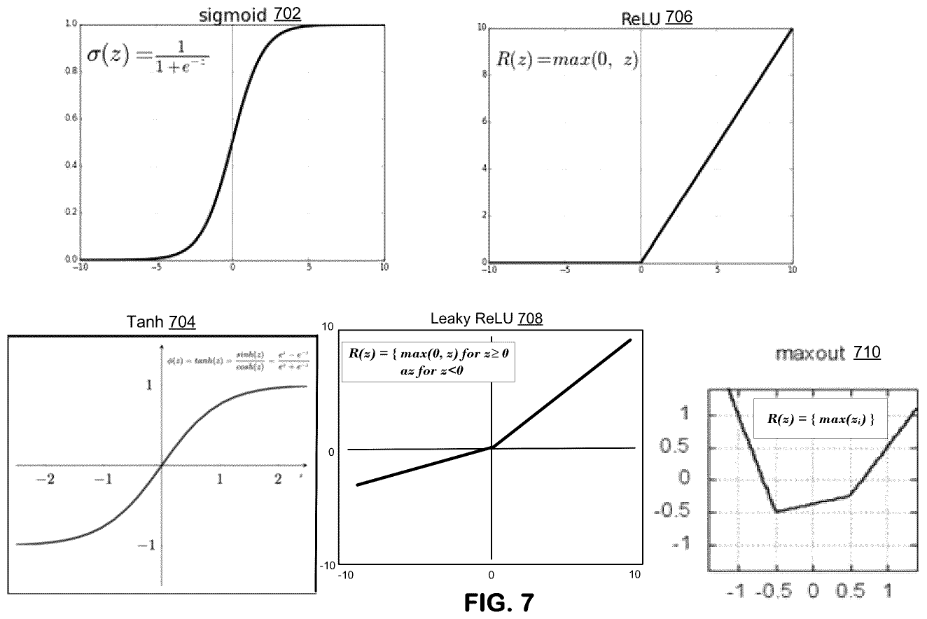

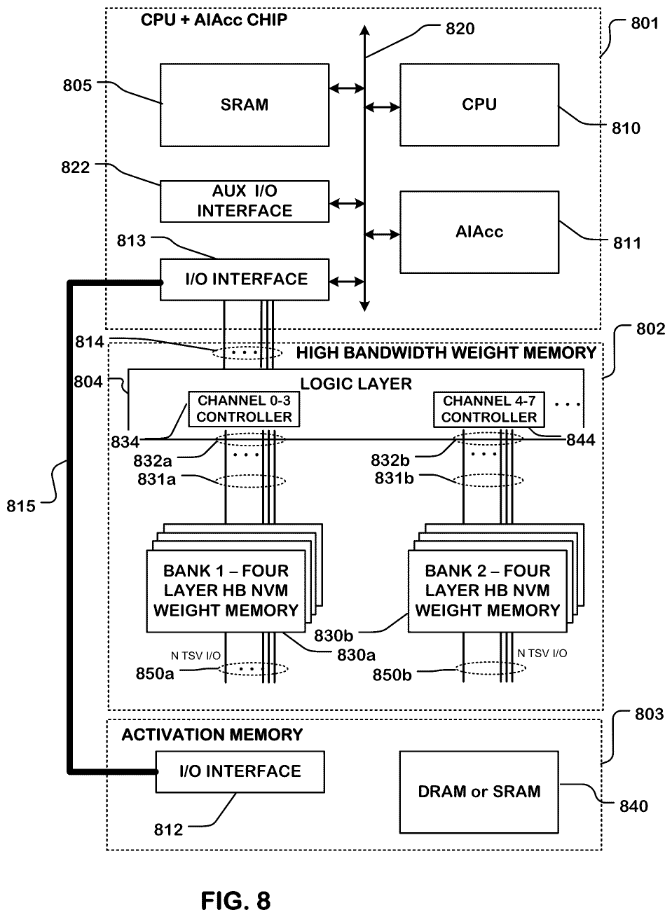

FIG. 3 is a schematic illustration of a technique of allocating weight data among multiple NVM channels by a high bandwidth NVM in accordance with the technologies as described herein. High bandwidth memory architecture 300 illustrated by FIG. 3 incorporates the use of channels 310, 311, 312 to enable data to be read from or stored to different NVM dies carrying memory arrays contemporaneously. Such memory channels used for data transfer along pathways to and from dies implementing non-volatile storage arrays. In some implementations, a channel controller can be shared by, i.e., can control, multiple channels as illustrated by 834, 844 in FIG. 8, which control channels 0-3 and channels 4-7 respectively.

In an implementation and by way of example, if a memory system has 4 channels, or multichannel NVM memory, the total weight data length can be distributed equally or otherwise among the memory channels (data length/channel). Of course, utilization of page size can be maximized using the techniques described above with reference to FIGS. 1-2. For example: 288 weights per neural network channel, e.g., 288 red weights (e.g., 32 filters×9 weights per filter), can be distributed among 4 memory channels, yielding 72 red weights per each memory channel, or 72 red weights/9 weights per filter yields 8 red filters per memory channel. Analogously, 8 green filters per memory channel; and 8 blue filters per memory channel.

Further, different layers of the neural network will employ different groups of weights. As shown in FIG. 3, for example, in the convolutional neural network (CNN), there are different layers 320A, 322A. For each layer, there are different filters 320B, 322B. Here, layer 0 is the first layer 320A in convolutional neural network and corresponds to the first layer filter (weights) 320B are stored in the page 0. If page 0 is not large enough, the weights data will be stored at a following page. Further, weights can be of a different type, and function for the different layers. For example, weights associated with layer 0 320B include weights grouped according to red, green and blue filters. Layer 1 322A includes weights grouped according to some other paradigm defined by the neural network definition. In some implementations, the weights corresponding to a first layer of a neural network can be stored according to one paradigm (e.g., 201, 202, or 203 of FIG. 2) and weights corresponding to a second layer of the neural network can be stored according to a different paradigm.

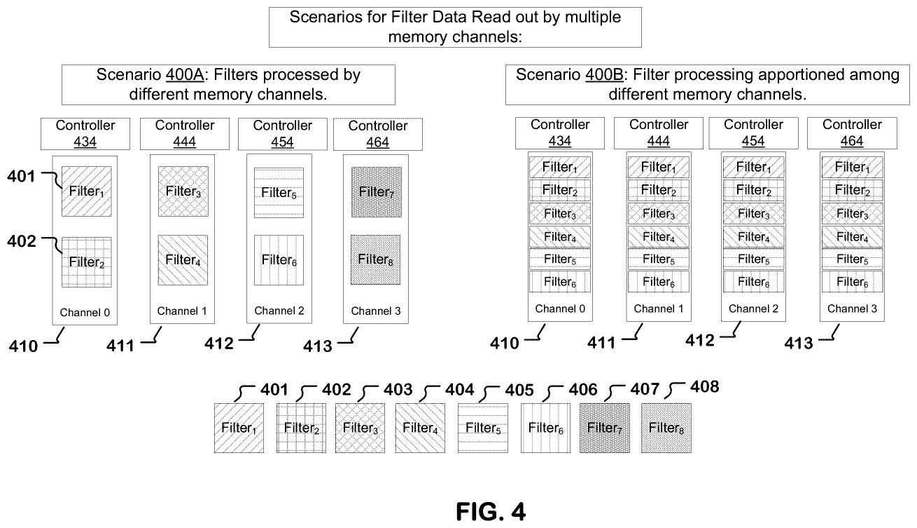

FIG. 4 is a schematic diagram illustrating multiple scenarios for allocating weight data among multiple NVM channels by a high bandwidth NVM in accordance with the technologies as described herein. Appropriate storage scenarios according to the present technology can provide for retrieval of the weights for two or more groups of weights (e.g., filters) without necessitating a read of an additional page of memory. For example, weights can be stored such that retrieval of all groups for the layer can be performed without necessitating triggering additional page of memory. In FIG. 4, weight data belonging to a plurality of filters (filter 1-filter 7) 401-408 can be read out by multiple memory channels (channel 0-channel 3) 410-413. A memory channel is used for data transfer via pathways to and from NVM dies implementing non-volatile storage arrays. In some implementations, the controller can be shared by, i.e., can control, multiple channels as illustrated by 834, 844 in FIG. 8, which control channels 0-3 and channels 4-7 respectively.

In scenario 400A, weights grouped according to filters can be allocated to individual memory channels. For example, the weights for filter 1 401 and filter 2 402 are stored for retrieval by channel 0 410. Accordingly, weights from filters can be stored to or retrieved from multiple arrays contemporaneously using multiple NVM channels. In this configuration, weights belonging to different filters can be read contemporaneously using different channels, however, if weights from different groups assigned to the same channel need to be read, for example from filter 1 and filter 2 in scenario 400A of FIG. 4, both belonging to channel 0 410, then multiple page reads might need to occur.

In scenario 400B, weights grouped according to filters are allocated to storage space across different channels. With reference to FIG. 4, the weights for filter 1 through filter 6 401-406 are apportioned among each of the four available channels (channel 0-channel 3) 410-413. In this scenario, weight data distributed among the multiple channels can be read in contemporaneously from NVM arrays by each of channel 0 through channel 3 410-413. Further, read operations against the NVM arrays of each channel have the capability to read weight data for each of the filters without necessitating a page retrieval when switching read operations from one filter to the next filter.

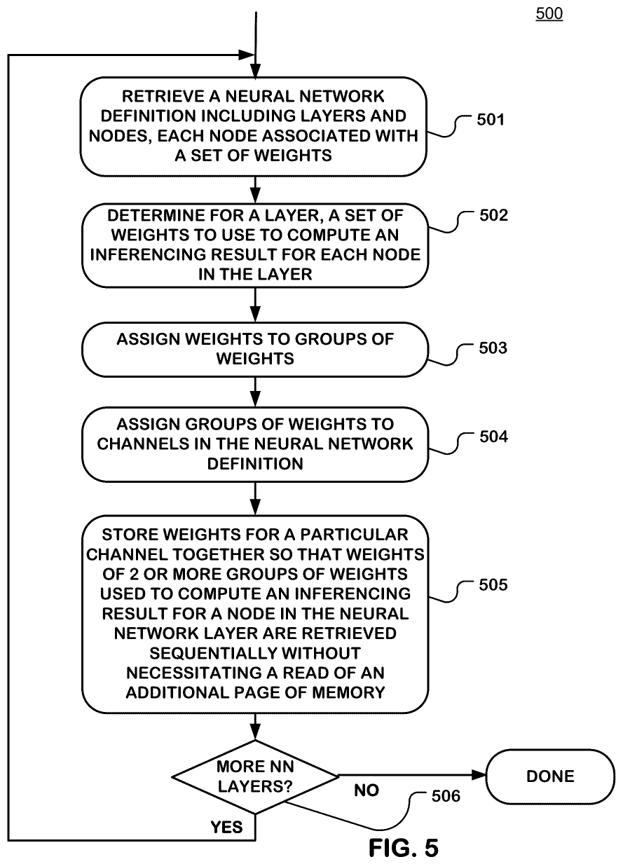

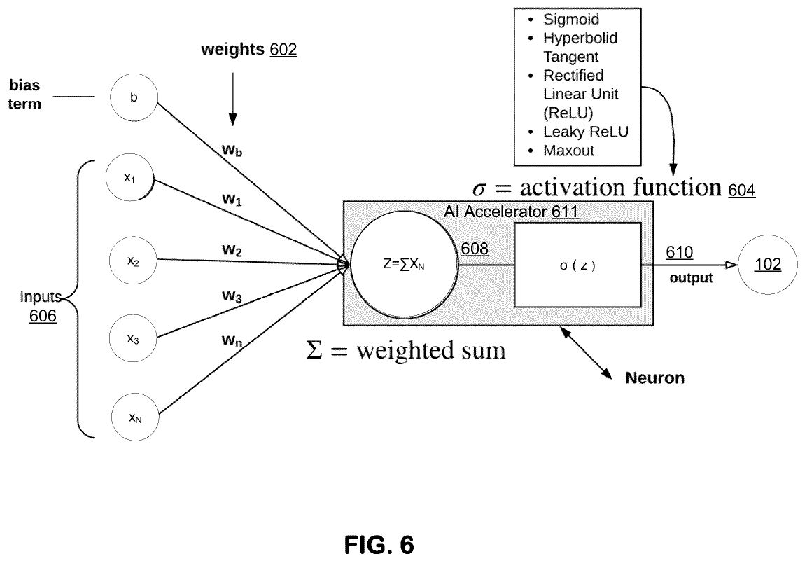

FIG. 5 is a flowchart illustrating an example of logic of a weight data storage operation that can be executed by an inference system, such as described with reference to FIGS. 1-4. FIG. 6 is a simplified functional block diagram of a representative neural network node (neuron) including weight data stored into and read out from a high bandwidth NVM by the AI inference system logic as described herein. The logic can be implemented using machine executable instructions stored in memory, such as the SRAM on-chip memory 805, or other memory accessible by the processor 810 coupled with a logic layer die including channel logic implementing connections between a plurality of channels conducting data to and from an accelerator core via at least one bus, and a plurality of NVM dies stacked vertically one above another, forming a layered vertical stack of NVM dies, each of the NVM dies including at least one memory chip and a plurality of direct vertical connections to a corresponding channel logic in the logic layer. FIG. 8 is discussed in more detail below, following the discussion regarding FIGS. 5-7. In this example, a collection of weights for artificial intelligence neural network computations downloaded from an external source, such as a network, is loaded into the high bandwidth NVM of the inference system.

With reference to FIGS. 5, 6, and 7, during runtime, an operation retrieves a neural network definition that includes layers and nodes, each node associated with weights 602 (e.g., Wb, W1, W2, W3, and Wn) (operation 501). This definition may be stored in the high bandwidth NVM (e.g., 802 of FIG. 8), or an auxiliary memory (e.g., 803 of FIG. 8) or otherwise obtained from an external source off chip. Sets of weight data are determined for the layer of the neural network to perform calculations (operation 502).

After sets of weights are determined for the layer, the weights are assigned to groups (operation 503) for one or more nodes of the neural network layer.

Next, the groups of weights (e.g., 211, 212, 213) are assigned to channels (operation 504) in the neural network definition. For example, in operation 504, the weights for red filters can be assigned to the red channel of a neural network. The resulting groupings of weights for the channels are stored in the high bandwidth NVM, e.g., memory 802, such that weights for a particular channel can be stored together so that weights of 2 or more groups of weights used to compute an inferencing result for a node in the neural network layer are retrieved sequentially without necessitating a read of an additional page of memory (operation 505). The procedure includes checking if nodes at further neural network layers are to be processed (operation 506) and if so, restarting operations 501 to 506 for the next batch of neural network nodes to be processed. If there are no further layers to process then all weights for the neural network definition have been successfully stored.

Thus, the operations of FIG. 5 include an operation to neural network definition data defining layers and nodes, each node associated with a set of weights. Also, as shown in FIG. 5, after determining weights to use to compute an inferencing result for nodes in a layer, assigning the weights to groups of weights and assigning the groups of weights to channels in the neural network definition, the weights are stored for a particular channel together so that the weights of 2 or more groups of weights used to compute an inferencing result for a node in the neural network layer are retrieved sequentially without necessitating a read of an additional page of memory, the operations loop to operation 501, to process a next layer of the neural network. As discussed above with reference to FIG. 4, operation 505 can optionally include allocating or apportioning weights belonging to some groups across multiple memory channels in multi-channel HBW memory architectures. If more neural network nodes are to be processed, the operations 501 to 506 are repeated, and can include loading the weights for the nodes of the next neural network layer.

It will be appreciated with reference to FIG. 5, that many of the steps can be combined, performed in parallel or performed in a different sequence without affecting the functions achieved. In some cases, as the reader will appreciate, a rearrangement of steps will achieve the same results only if certain other changes are made as well. In other cases, as the reader will appreciate, a rearrangement of steps will achieve the same results only if certain conditions are satisfied. Furthermore, it will be appreciated that the flow charts herein show only steps that are pertinent to an understanding of the present technology, and it will be understood that numerous additional steps for accomplishing other functions can be performed before, after and between those shown.

Referring to FIG. 8, during training processing, weights stored in NVM dies (e.g., of the weights memory 802) are adjusted by the processor chip 801 (e.g., a CPU and an AIAcc) based upon training dataset(s). As training progresses, the processor chip 801 will keep updating values for the weights and this value will be stored in the NVM. In some implementations, weights are fixed during inference processing.

FIG. 8 is a simplified functional block diagram of an inference system as described herein. The platform includes a processor chip 801 (e.g., a CPU and an AIAcc), a first memory chip 803 (an activation memory storing activation data), and a second memory chip 802 (e.g., a weigh memory storing weight data for a neural network). The processor chip 801 in this example includes a CPU or processor core 810, accelerator core 811, on-chip memory 805, such as SRAM (or other type of memory) which can be used as working memory and as a cache memory, a first I/O interface 813 and a second I/O interface 822. A bus system 820 provides for intra-chip communications among the components of the processor chip 801.

The first memory chip 803 in this example comprises a high capacity, volatile memory 840 such as DRAM or SRAM (or a nonvolatile memory such as 3D NAND or other type of memory implemented using charge trapping storage technology), for example. The first memory chip 803 includes a first memory I/O interface 812 for off-chip communications. The first memory I/O interface 812 can comprise a high-speed serial port, such as a serial peripheral interface (SPI) compatible port, or a parallel port, depending on the particular implementation of the memory chip 803 that is utilized. A data path 815 is provided in this example between the first memory I/O interface 812, and the first I/O interface 813 on the processor chip 801. First memory chip 803 can store activation data in accordance with an activation function used to compute an inference result. With reference to FIG. 7, suitable activation data can include stored data implementing an activation function including one or more of a sigmoid function 702, a hyperbolic tangent (tanh) function 704, a rectified linear unit (ReLU) function 706, a leaky rectified linear unit (LReLU) function 708, and a maxout function 710.

Now with continued reference to FIG. 8, the second memory chip 802, in this example, comprises a HBW NVM configured in one or more banks 830a, 830b, each of which can comprise one or more layers of NVM dies arranged in channels. The NVM can be one of a phase change memory (PCM), a three-dimensional cross point memory (3D Xpoint), and a NAND flash memory. In other examples, the second memory chip 802 can comprise NOR flash memory using charge trapping storage technology, or other suitable random-access technologies like resistive RAM (e.g. metal oxide memory), magnetic RAM, Ferroelectric RAM a conductive bridge random-access memory CBRAM and so on.

The second memory chip 802 includes a memory I/O interface 814 for off-chip communications via a logic layer 804 to the I/O interface 813 on the processor chip 801. Logic layer 804 includes channel controllers 834, 844 that provide control of multiple channels forming one or more sets of high-speed data pathways on which weight data can flow across an interface 832a, 832b exposed on a surface of the logic layer 804, and complementary to the interface 831a, 831b on a surface of banks 830a, 830b of NVM dies arranged in layers direct connected by vertical connections 850a, 850b at the surfaces provided between the IO-memory interface 832a, 832b and the memory-IO interface 831a, 831b. The direct vertical connections 850a, 850b can comprise very short length copper via-to-via conductors or other chip-to-chip contact technologies suitable for high speed, low latency, and low power communication between the chips. In an implementation and by way of example, two stacks are formed by stacking four NVM dies with N/8 through silicon via (TSV) I/O per die onto a logic die; wherein N is the total number of TSV IO, and 8 is number of dies; N/8 is IO per die. One NVM die has one channel; one channel is N/8 through silicon via (TSV) I/O. Each channel is completely independent so each channel can operate independently. One controller can control multiple channels. An external controller can be provided in a field programmable gate array (FPGA) or system on a chip (SoC) die (e.g., implementing processor 801).

DRAM is an option to bond into the system in package (SiP) in case on-chip SRAM is not big enough.

Thermal (heat) management can used to guarantee data retention.

An AI accelerator (e.g. accelerator core 811), as the term is used herein, is a configurable logic circuit including components designed or suitable for execution of some or all of the arithmetic operations of AI inference operations. Configuration of the accelerator core can include loading a set of weights from memory 802 to be used in conducting inference operations, or parts of the set of weights. In some embodiments, configuration of the accelerator core can include loading some or all of the of the computation graphs of an inference model that define the sequence and architecture of the operation of the inference model. The inference model can comprise a computation graph of a deep learning neural network, in some examples having a plurality of fully connected and partially connected layers, activation functions, normalization functions and so on.

An accelerator core can be implemented using configurable logic, like arrays of configurable units used in field programmable gate arrays for example, in which compiled computation graphs are configured using bit files. An accelerator core can be implemented using a hybrid of data flow configurable logic and sequential processing configurable logic.

A runtime processor core (e.g. CPU 810) can execute a runtime program to coordinate operation of the accelerator core to accomplish real time inference operations, including data input/output operations, loading computation graphs, moving the set of weights to be applied in the inference operation into and out of the accelerator core, delivering input data to the accelerator core, and performing parts of the computations to obtain inference results.

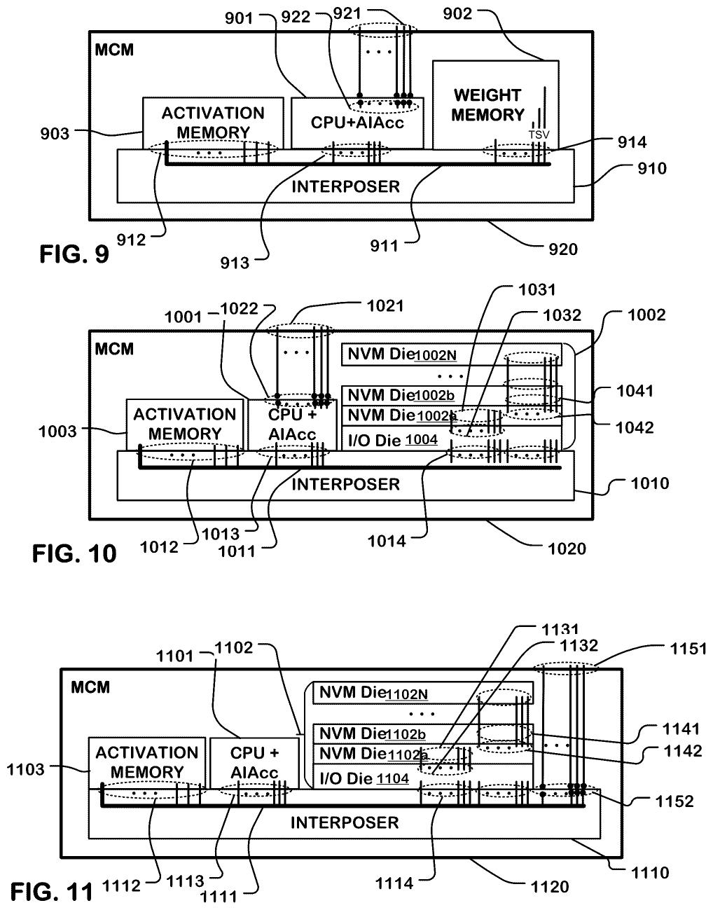

FIGS. 9-11 provide example arrangements of an inference system with high bandwidth NVM as described herein, showing varieties of configurations of the chips and connections among the chips, the interposer and external contacts of the package. Other arrangements can be implemented as suits a particular need.

FIG. 9 illustrates a multichip module (MCM) 920 that includes a processor chip 901, a first memory chip 903 (e.g., an activation memory storing activation data), and second memory chip 902 (e.g., a weight memory storing weight data for a neural network). The weight memory can be considered HBW memory. In this example, mounted on an interposer 910 (or substrate) are the processor chip 901, the second memory chip 902, which can be a HBW NVM for storing weights (e.g., weight data) used in neural network computations, and the first memory chip 903, which can be dynamic random access memory (DRAM), static random access memory (SRAM) or NAND, however DRAM and SRAM are presently preferred options, for storing activation data for activation functions used in neural network computations. The assembly is configured as a multichip module 920 in a single package.

The processor chip 901 can include a runtime processor core (e.g. CPU) and an accelerator core, such as an artificial intelligence accelerator (e.g. AIAcc) or a neuron processing unit (NPU).

In this example, processor chip 901 includes an input/output interface 913 disposed on the surface of the chip 901. The input/output interface 913 is connected to interconnection wiring 911 on the interposer 910.

The first memory chip 903 includes an interface 912 for connection to the interconnection wiring 911 on the interposer 910. The second memory chip 902 includes an interface 914 for connection to the interconnection wiring 911 on the interposer 910. While depicted as a single entity in FIG. 9 for clarity, second memory 902 can comprise multi-layered stack, in which memory dies are disposed on different layers and can be connected to vertical connectors such as through silicon via (TSV) connections to interconnection wiring 911 on the interposer 910.

Thus, interconnection wiring 911 provides part of the data path between the first memory chip 903, the second memory chip 902, and the processor chip 901.

In the example illustrated in FIG. 9, the processor chip 901 includes another input/output interface 922 for connection to external contact structures 921 of the multichip module 920.

FIG. 10 illustrates another configuration of an inference system as described herein. This configuration includes a processor chip 1001, a first memory chip 1003 (e.g., an activation memory storing activation data), and a second memory chip 1002 (e.g., a weight memory storing weight data for a neural network), which can be considered HBW memory. In this example, the second memory chip 1002 comprises individual layered NVM dies 1002a-1002N mounted to an I/O die 1004 implementing connection logic in a logic layer. The processor chip 1001, the I/O die 1004 of the second memory chip 1002, and the first memory chip 1003 are mounted on an interposer 1010 (or substrate). The assembly is configured as a multichip module (MCM) 1020 in a single package.

The processor chip 1001 can include a runtime processor core (e.g. CPU) and an accelerator core, such as an artificial intelligence accelerator (e.g. AIAcc) or a neuron processing unit (NPU).

The second memory chip 1002 includes the plurality of non-volatile memory dies 1002a-1002N stacked one on top of another and stacked above the I/O die 1004. One such NVM die 1002a illustrated includes a chip-to-chip bonding surface on which an interface 1031 is exposed for connection to the I/O die 1004. The I/O die 1004 includes an interface 1032 exposed on a surface of the I/O die 1004, and complementary to the interface 1031 on the NVM die 1002a. In this example, direct vertical connections at the surfaces are provided between the memory interface 1032 and the interface 1031. The direct vertical connections can comprise very short length copper via-to-via conductors or other chip-to-chip contact technologies suitable for high speed, low latency, and low power communication between the chips.

With continuing reference to the second memory chip 1002, another NVM die 1002b illustrated includes a chip-to-chip bonding surface on which an interface 1041 (e.g., an NVM-NVM interface) is exposed for connection to NVM die 1002a of the second memory chip 1002. The NVM die 1002a includes an interface 1042 (e.g., an NVM-NVM interface) exposed on a surface of the NVM die 1002a, and complementary to the interface 1041 on the NVM die 1002b. In this example, direct vertical connections at the surfaces are provided between the NVM-NVM interface 1042 and the NVM-NVM interface 1041.

In some implementations, an interposer layer provides connection between the plurality of direct vertical connections of the vertical stack (e.g., NVM dies 1002a-1002N) to corresponding channel logic in the logic layer (e.g., I/O die 1004). In some implementations, a plurality of solder bumps that have been deposited onto chip pads of the logic layer (e.g., I/O die 1004) and the plurality of NVM dies (e.g., 1002a-1002N) provide connection with a device immediately below. In some implementations, a plurality of backside interconnects have been deposited onto chip pads of the logic layer and the plurality of NVM dies provide wafer-to-wafer connection with a device above. The AI inference memory device can be packaged as any of a 10.5D through silicon via (TSV) integrated circuit, a three-dimension (3D) through silicon via (TSV) integrated circuit and a three-dimensional (3D) system-on-chip (3D SOC) integrated circuit.

In this example, the processor chip 1001 includes an input/output interface 1013 disposed on the surface of the chip 1001. The input/output interface 1013 is connected to interconnection wiring 1011 on the interposer 1010.

The first memory chip 1003 includes an interface 1012 for connection to the interconnection wiring 1011 on the interposer 1010.

Also, the I/O chip 1004 includes an interface 1014 for connection to the interconnection wiring 1011 on the interposer 1010.

Thus, interconnection wiring 1011 provides part of the data path between the first memory chip 1003 and the second memory chip 1002, and the processor chip 1001.

In the example illustrated in FIG. 10, the processor chip 1001 includes another input/output interface 1022 for connection to external contact structures 1021 of the multichip module 1020.

FIG. 11 illustrates another configuration of an inference system as described herein. This configuration includes a processor chip 1101, a first memory chip 1103 (e.g., an activation memory storing activation data), and a second memory chip 1102 (e.g., weight memory storing weight data for a neural network), which can be considered HB memory. In this example, the second memory chip 1102 comprises individual layered non-volatile memory (NVM) dies 1102a-1102N mounted to an I/O die 1104. The processor chip 1101, the I/O die 1104 of the second memory chip 1102, and the first memory chip 1103 are mounted on an interposer 1110 (or substrate). The assembly is configured as a multichip module (MCM) 1120 in a single package.

The processor chip 1101 can include a runtime processor core (e.g. CPU) and an accelerator core, such as an artificial intelligence accelerator (e.g. AIAcc) or a neuron processing unit.

The second memory chip 1102 includes the plurality of non-volatile memory dies 1102a-1102N stacked one on top of another and stacked above an I/O die 1104. One such NVM die 1102a illustrated includes a chip-to-chip bonding surface on which an interface 1131 is exposed for connection to the I/O die 1104. The I/O die 1104 includes an interface 1132 exposed on a surface of the I/O die 1104, and complementary to the interface 1131 on the NVM die 1102a. In this example, direct vertical connections at the surfaces are provided between the interface 1132 and the interface 1131. The direct vertical connections can comprise very short length copper via-to-via conductors or other chip-to-chip contact technologies suitable for high speed, low latency, and low power communication between the chips.

With continuing reference to second memory chip 1102, another NVM die 1102b illustrated includes a chip-to-chip bonding surface on which an interface 1141 (e.g., an NVM-NVM interface) is exposed for connection to NVM die 1102a the second memory chip 1102. The NVM die 1102a includes an interface 1142 (e.g., an NVM-NVM interface) exposed on a surface of the NVM die 1102a, and complementary to the interface 1141 on the NVM die 1102b. In this example, direct vertical connections at the surfaces are provided between the NVM-NVM interface 1142 and the NVM-NVM interface 1141.

In some implementations, interposer layer 1110 provides connection between the plurality of direct vertical connections of the vertical stack (e.g., NVM chips 1102a-1102N) to corresponding channel logic in the logic layer (e.g., I/O die 1104). In some implementations, a plurality of solder bumps that have been deposited onto chip pads of the logic layer (e.g., I/O die 1104) and the plurality of NVM dies (e.g., 1102a-1102N) provide connection with a device immediately below. In some implementations, a plurality of backside interconnects have been deposited onto chip pads of the logic layer and the plurality of NVM dies provide wafer-to-wafer connection with a device above. The AI inference memory device can be packaged as any of a 2.5D through silicon via (TSV) integrated circuit, a three-dimension (3D) through silicon via (TSV) integrated circuit and a three-dimensional (3D) system-on-chip (3D SOC) integrated circuit.

In this example, processor chip 1101 includes an input/output interface 1113 disposed on the surface of the chip 1101. The input/output interface 1113 is connected to interconnection wiring 1111 on the interposer 1110.

The first memory chip 1103 includes an interface 1112 for connection to the interconnection wiring 1111 on the interposer 1110.

Also, the I/O die 1104 includes an interface 1114 for connection to the interconnection wiring 1111 on the interposer 1110.

Thus, interconnection wiring 1111 provides part of the data path between the first memory chip 1103 and the second memory chip 1102, and the processor chip 1101.

In the example illustrated in FIG. 11, the multichip module (MCM) 1120 includes another input/output interface 1152 for connection to external contact structures 1151 of the multichip module 1120.

Other implementations of the method described in this section can include a non-transitory computer readable storage medium storing instructions executable by a processor to perform any of the methods described above. Yet another implementation of the method described in this section can include a system including memory and one or more processors operable to execute instructions, stored in the memory, to perform any of the methods described above.

Any data structures and code described or referenced above are stored according to many implementations on a computer-readable storage medium, which may be any device or medium that can store code and/or data for use by a computer system. This includes, but is not limited to, volatile memory, non-volatile memory, application-specific integrated circuits (ASICs), field-programmable gate arrays (FPGAs), magnetic and optical storage devices such as disk drives, magnetic tape, CDs (compact discs), DVDs (digital versatile discs or digital video discs), or other media capable of storing computer-readable media now known or later developed.

As used herein, a network node, including network nodes referred to as client side nodes and a server side nodes, is an application hosted on an active electronic device, or virtual device executed in an active electronic device such as a cloud-based platform, that is attached to a network, and is capable of sending, receiving, or forwarding information in support of computer programs such as servers and clients, over a physical media for a communications channel on the network, and having for example media access control addresses and protocol stacks that support higher network layers. A network can include the networks using Internet Protocol addresses, or other type of network layer addresses. In some embodiments the network comprises the Internet. Examples of electronic devices which can host network nodes, include all varieties of computers, workstations, laptop and desktop computers, hand-held computers and smart phones, and cloud-based platforms.

A byte is a basic storage unit used in many integrated circuit logic and memory circuits, and consists of eight bits. Basic storage unit can have other sizes, including for example one bit, two bits, four bits, 16 bits and so on. Thus, the description of weight data optimization for high bandwidth (HBW) non-volatile memories in AI inferencing systems as set out above, and in other examples described herein utilizing the term byte, applies generally to circuits using different sizes of storage units, as would be described by replacing the term byte or set of bytes, with storage unit or set of storage units. Also, in some embodiments different sizes of storage units can be used in a single command sequence, such as one or more four bit storage units combined with eight bit storage units.

A number of flowcharts illustrating logic executed by a memory controller or by memory device are described herein. The logic can be implemented using processors programmed using computer programs stored in memory accessible to the computer systems and executable by the processors, by dedicated logic hardware, including field programmable integrated circuits, and by combinations of dedicated logic hardware and computer programs. With all flowcharts herein, it will be appreciated that many of the steps can be combined, performed in parallel or performed in a different sequence without affecting the functions achieved. In some cases, as the reader will appreciate, a re-arrangement of steps will achieve the same results only if certain other changes are made as well. In other cases, as the reader will appreciate, a re-arrangement of steps will achieve the same results only if certain conditions are satisfied. Furthermore, it will be appreciated that the flow charts herein show only steps that are pertinent to an understanding of the present technology, and it will be understood that numerous additional steps for accomplishing other functions can be performed before, after and between those shown.

While the present technology is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the present technology and the scope of the following claims.

What is claimed is:

1. A method for storing weight data used to compute node values during artificial intelligence (AI) inferencing operations conducted by a neural network, the method comprising:
receiving a neural network definition defining a neural network having a plurality of layers, each layer comprising a plurality of neural network nodes, each neural network node using one or more weights to compute a result for the neural network node by applying a function to (i) the one or more weights and (ii) an input to the neural network node during an inferencing operation;
determining, for a layer of the plurality of layers defined in the neural network definition, a set of weights to use to compute a neural network inferencing result for each neural network node of the plurality of neural network nodes in the layer; and
storing the set of weights determined for the layer in a page of memory, such that any weights, of the set of weights, used to compute the neural network inferencing result for each neural network node of the plurality of neural network nodes in the layer are stored together in the page of memory for retrieval together.

2. The method of claim 1, further including processing a next layer in the neural network definition, such that a second set of weights used to compute a neural network inference result for the next layer are also stored together in the page of memory for retrieval together.

3. The method of claim 1, wherein weights in the set of weights are assigned to groups of weights and each group of weights is assigned to a channel in the neural network definition, and wherein the storing further includes storing weights of a particular channel together such that weights of two or more groups of weights used to compute the neural network inferencing result for each neural network node of the plurality of neural network nodes in the layer are retrieved sequentially without necessitating a read of an additional page of memory.

4. The method of claim 3, wherein the retrieving of the weights of the two or more groups of weights further includes retrieving all groups for a layer without necessitating a read of an additional page of memory.

5. The method of claim 3, wherein each group of weights corresponds to a particular channel of the neural network.

6. The method of claim 5, wherein each channel of the neural network corresponds to a filter populated by the weights of a respective group of weights.

7. The method of claim 6, wherein the filter of each corresponding channel comprises weights arranged in a pattern selected from a 3×3 pattern, a 4×4 pattern, a 5×5 pattern, and a 6×6 pattern.

8. The method of claim 3, wherein weights are stored to and read from one or more NVM dies implementing non-volatile storage arrays, and wherein a plurality of memory channels facilitate transfer of the weights along pathways to and from the one or more NVM dies.

9. The method of claim 8, wherein all weights belonging to a group are allocated to a particular memory channel.

10. The method of claim 8, wherein weights belonging to a group are apportioned among multiple memory channels.

11. The method of claim 1, further comprising retrieving each weight in the set of weights from a previous storage location in memory prior to storing the set of weights determined for a layer in a page of memory; thereby re-arranging weight data in the memory.

12. An artificial intelligence (AI) inference memory device, comprising:
a plurality of non-volatile memory (NVM) dies, each of the NVM dies including at least one memory array and a plurality of connections to corresponding channel logic to provide storage into and retrieval from the memory array;
wherein a neural processing unit (NPU) implementing an accelerator core connected via the corresponding channel logic for transmitting data to and from the memory arrays is configured to implement operations including:
receiving a neural network definition defining a neural network having a plurality of layers, each layer comprising a plurality of neural network nodes, each neural network node using one or more weights to compute a result for the neural network node by applying a function to (i) the one or more weights and (ii) an input to the neural network node during an inferencing operation;
determining, for a layer of the plurality of layers defined in the neural network definition, a set of weights to use to compute a neural network inferencing result for each neural network node of the plurality of neural network nodes in the layer; and
storing the set of weights determined for the layer in a page of memory of the memory arrays, such that any weights, of the set of weights, used to compute the neural network inferencing result for each neural network node of the plurality of neural network nodes in the layer are stored together in the page of memory for retrieval together.

13. The AI inference memory device of claim 12, wherein the plurality of NVM dies include NAND flash.

14. The AI inference memory device of claim 12, wherein weights in the set of weights are assigned to groups of weights and each group of weights is assigned to a channel in the neural network definition, and wherein the storing further includes storing weights of a particular channel together such that weights of two or more groups of weights used to compute the neural network inference result for each neural network node of the plurality of neural network nodes in the layer are retrieved sequentially without necessitating a read of an additional page of memory of the memory arrays.

15. The AI inference memory device of claim 14, wherein the retrieving of the weights of the two or more groups of weights further includes retrieving all groups for a layer without necessitating a read of an additional page of memory of the memory arrays.

16. The AI inference memory device of claim 12, wherein weights are stored to and read from one or more of the NVM dies, and wherein a plurality of memory channels facilitate transfer of the weights along pathways to and from the one or more NVM dies.

17. The AI inference memory device of claim 16, wherein all weights belonging to a group are to a particular memory channel.

18. The AI inference memory device of claim 16, wherein weights belonging to a group are apportioned among multiple memory channels.

19. The AI inference memory device of claim 12, wherein the operations further comprise retrieving each weight in the set of weights from a previous storage location in memory prior to storing the set of weights determined for a layer in a page of memory of the memory arrays;
thereby re-arranging weight data in at least one of the NVM dies.

20. An artificial intelligence (AI) inferencing system, comprising:
a substrate coupling:
an AI inference memory device for storing arrays of weights, the memory device comprising a plurality of non-volatile memory (NVM) dies, each of the NVM dies including at least one memory array and a plurality of connections to corresponding channel logic to provide storage into and retrieval from the memory array; and
a neural processing unit (NPU) implementing an accelerator core connected via the corresponding channel logic for conducting data to and from the memory arrays;
wherein the neural processing unit is configured to implement:
receiving a neural network definition defining a neural network having a plurality of layers, each layer comprising a plurality of neural network nodes, each neural network node using a particular set of weights to compute a node value for the neural network node by applying a function to the particular set of weights and an input to the neural network node during an inferencing operation;
determining for a layer of the plurality of layers defined in the neural network definition, a set of weights to use to compute a neural network inferencing result for each neural network node of the plurality of neural network nodes in the layer; and
storing the set of weights determined for the layer in a page of memory, such that any weights used to compute the neural network inferencing result for each neural network node of the plurality of neural network nodes in the layer are stored together in the page of memory for retrieval together.

21. A non-transitory memory storing instructions for storing weight data used to compute node values during artificial intelligence (AI) inferencing operations conducted by a neural network, which when, executed by one or more processors implement actions including:
receiving a neural network definition defining a neural network having a plurality of layers, each layer comprising a plurality of neural network nodes, each neural network node using one or more weights to compute a result for the neural network node by applying a function to (i) the one or more weights and (ii) an input to the neural network node during an inferencing operation;
determining, for a layer of the plurality of layers defined in the neural network definition, a set of weights to use to compute a neural network inferencing result for each neural network node of the plurality of neural network nodes in the layer; and
storing the set of weights determined for the layer in a page of memory, such that any weights, of the set of weights, used to compute the neural network inferencing result for each neural network node of the plurality of neural network nodes in the layer are stored together in the page of memory for retrieval together.
